(19) United States
(12) Patent Application Publication
(10) Pub. No.: US 2023/0381906 A1
(43) Pub. Date: Nov. 30, 2023

(54) CUTTING APPARATUS

(71) Applicant: DISCO CORPORATION, Tokyo (JP)

(72) Inventor: Kenji TAKENOUCHI, Tokyo (JP)

(21) Appl. No.: 18/317,266

(22) Filed: May 15, 2023

(30) Foreign Application Priority Data
May 30, 2022 (JP) 2022-087428

(51) Int. Cl. B23Q 11/02; B23Q 11/10

(52) U.S. Cl. CPC B23Q 11/02; B23Q 11/10

(57) ABSTRACT

A cutting apparatus includes a cutting liquid supply nozzle that is disposed adjacent to a cutting unit and supplies a cutting liquid to a contact point between a cutting blade and a workpiece and a chemical liquid supply nozzle that has a length in a Y-axis direction which is greater than the width of the workpiece and supplies a chemical liquid for preventing adhesion of cutting swarf to a front surface of the workpiece.

### BACKGROUND OF THE INVENTION

### Field of the Invention

The present invention relates to a cutting apparatus for cutting a workpiece.

### Description of the Related Art

A wafer formed on a front surface thereof with a plurality of devices such as integrated circuits (ICs) and large-scale integration (LSI) circuits in the state of being partitioned by a plurality of intersecting projected dicing line (streets) is divided into individual device chips by a cutting apparatus including a cutting blade in a rotatable manner, and the thus divided device chips are used for electric apparatuses such as mobile phones and personal computers.

The cutting apparatus includes a chuck table that holds a wafer, a cutting unit that includes, in a rotatable manner, a cutting blade for cutting the wafer held by the chuck table, an X-axis feeding mechanism for relative cutting-feeding of the chuck table and the cutting unit in an X-axis direction, and a Y-axis feeding mechanism for relative indexing-feeding of the chuck table and the cutting unit in a Y-axis direction, and can divide the wafer into individual device chips with high accuracy.

In addition, when the wafer is cut by the above-mentioned cutting blade, cutting swarf (contaminants) may float on and be adhered to the front surface of the wafer, thereby lowering the quality of the devices. In view of this, there has been proposed a technology of supplying cleaning water to the front surface of the wafer to wash away the cutting swarf and thereby prevent adhesion of the cutting swarf to the devices (refer to Japanese Patent Laid-open No. 2014-121738).

### SUMMARY OF THE INVENTION

However, even when the cleaning water is supplied based on the technology described in the above-mentioned Japanese Patent Laid-open No. 2014-121738, it is difficult to efficiently wash away the cutting swarf, adhesion to the devices cannot be sufficiently prevented, and hence there is a demand for proposal of further solution.

Accordingly, it is an object of the present invention to provide a cutting apparatus that is able to efficiently prevent adhesion of cutting swarf to devices.

In accordance with an aspect of the present invention, there is provided a cutting apparatus including a chuck table that holds a workpiece, a cutting unit having, in a rotatable manner, a cutting blade for cutting the workpiece held by the chuck table, an X-axis feeding mechanism for relative cutting-feeding of the chuck table and the cutting unit in an X-axis direction, a Y-axis feeding mechanism for relative indexing-feeding of the chuck table and the cutting unit in a Y-axis direction orthogonal to the X-axis direction, a cutting liquid supply nozzle that is disposed adjacent to the cutting unit and supplies a cutting liquid to a contact point between the cutting blade and the workpiece, and a chemical liquid supply nozzle that has a length in the Y-axis direction which is greater than a width of the workpiece and supplies a chemical liquid for preventing adhesion of cutting swarf to a front surface of the workpiece.

Preferably, the cutting liquid supply nozzle supplies pure water or an aqueous solution of a neutral surface active agent, and the chemical liquid supply nozzle supplies any one of ammonia and aqueous hydrogen peroxide, a citric acid solution, sulfuric acid and aqueous hydrogen peroxide, ozone water, phosphoric acid and buffered hydrofluoric acid, and a phosphoric acid solution.

According to the cutting apparatus of the present invention, cutting swarf can be efficiently washed away from the front surface of the workpiece, and, further, lubricating properties and cooling properties for a cutting edge of the cutting blade can be maintained while corrosion of the cutting edge is prevented.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a general perspective view of a cutting apparatus according to an embodiment of the present invention;

FIG. 2 is a perspective view depicting, in an enlarged form, a cutting unit disposed in the cutting apparatus depicted in FIG. 1;

FIG. 3 is a plan view depicting a chemical liquid supply nozzle depicted in FIG. 2 and a wafer;

FIG. 4 is a perspective view depicting cutting according to the embodiment; and

FIG. 5 is a plan view of the cutting according to the embodiment depicted in FIG. 4.

### DETAILED DESCRIPTION OF THE PREFERRED EMBODIMENT

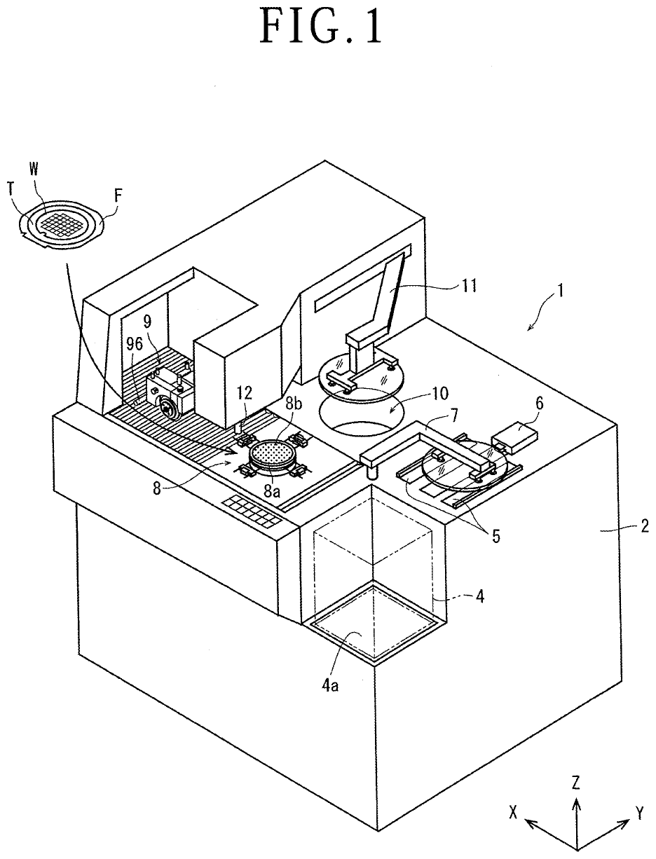

A cutting apparatus according to an embodiment of the present invention will be described in detail below with reference to the attached drawings. FIG. 1 depicts a general perspective view of a cutting apparatus 1 according to the present embodiment. A workpiece to be processed by the cutting apparatus 1 is, for example, a wafer W formed of silicon (Si).

The cutting apparatus 1 includes a cassette 4 (depicted in long and two short dashes line) that accommodates a plurality of wafers W as workpieces, a temporary placement table 5 on which the wafer W accommodated in the cassette 4 is conveyed out and temporarily placed, a conveying-in/out unit 6 that conveys out the wafer W from the cassette 4 onto the temporary placement table 5 and conveys in the wafer W from the temporary placement table 5 into the cassette 4, a conveying mechanism 7 that sucks the wafer W conveyed out onto the temporary placement table 5, swivels the wafer W, and places the wafer W on a holding surface 8b of a chuck table 8a of a holding unit 8, a cutting unit 9 that cuts the wafer W held under suction by the holding surface 8b of the chuck table 8a, a cleaning unit 10 (details are omitted) that cleans the wafer W cut by the cutting unit 9, a cleaning conveying mechanism 11 that conveys the cut wafer W from the chuck table 8a to the cleaning unit 10, an imaging unit 12 that images the wafer W on the chuck table 8a, and an unillustrated controller. The cassette 4 is mounted on a cassette table 4a disposed to be vertically movable by an unillustrated lifting mechanism, and, at the time of conveying out the wafer W from the cassette 4 by the conveying-in/out unit 6, the height of the cassette 4 is adjusted as required. Inside an apparatus housing 2, there are disposed an X-axis feeding mechanism for processing-feeding of the chuck table 8a of the holding unit 8 in an X-axis direction and a Y-axis feeding mechanism (both omitted in illustration) for indexing-feeding of the cutting unit 9 in a Y-axis direction orthogonal to the X-axis direction.

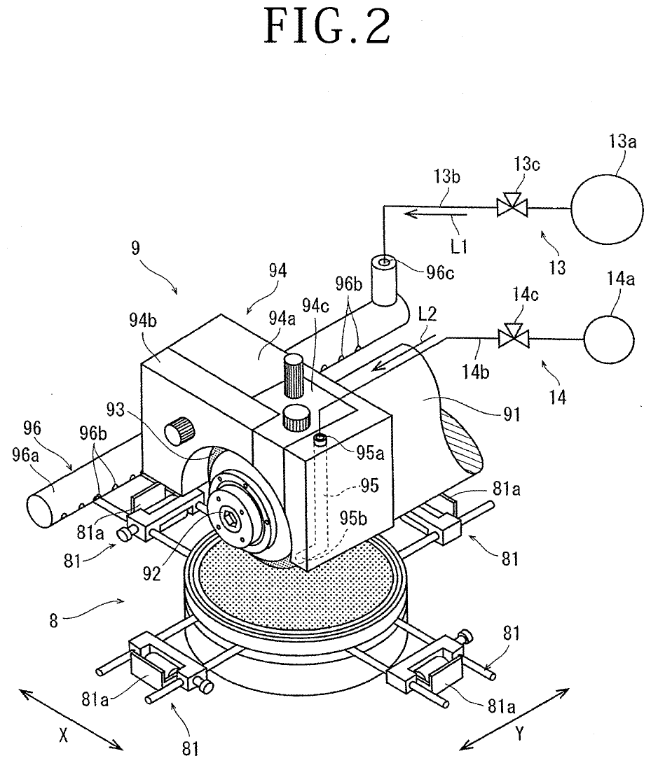

With reference to FIG. 2, the cutting unit 9 disposed in the cutting apparatus 1 depicted in FIG. 1 will be described specifically. FIG. 2 is a perspective view depicting, in an enlarged form, an essential part of the cutting unit 9 of the cutting apparatus 1 depicted in FIG. 1 and the holding unit 8 moved to a position directly under the cutting unit 9. As understood from FIG. 2, the cutting unit 9 includes a rotary shaft housing 91 extending in the Y-axis direction, a rotary shaft 92 rotatably supported by the rotary shaft housing 91, an annular cutting blade 93 detachably supported on a tip end side of the rotary shaft 92, a cover 94 that is mounted to the tip of the rotary shaft housing 91 and that covers the cutting blade 93, a cutting liquid supply nozzle 95 (depicted in broken line) that supplies a cutting liquid L2 to a contact point between the cutting blade 93 and the wafer W, that is, the cutting position, and a chemical liquid supply nozzle 96 that supplies a chemical liquid L1 (described in detail later) for preventing adhesion of cutting swarf to a front surface Wa of the wafer W. Note that the rotary shaft 92 is driven to be rotated by an unillustrated electric motor disposed on a rear end side of the rotary shaft 92. In addition, the cutting unit 9 in the present embodiment also includes a cutting-in feeding mechanism (omitted in illustration) that moves the cutting unit 9 in a Z-axis direction to perform cutting-in feeding, in addition to the above-mentioned Y-axis feeding mechanism.

As depicted in FIG. 2, the cover 94 includes a first cover member 94a fixed to the tip of the rotary shaft housing 91, a second cover member 94b fixed by a screw to a front surface of the first cover member 94a, and a cutting blade detection block 94c fixed by screws from an upper surface of the first cover member 94a. A blade sensor (omitted in illustration) for detecting wear or chipping on an outer circumferential edge part side of the cutting blade 93 is disposed in the cutting blade detection block 94c.

The chemical liquid supply nozzle 96 is disposed adjacent to the cutting unit 9. In the present embodiment, the chemical liquid supply nozzle 96 includes a hollow cylindrical main body section 96a disposed along the Y-axis direction, a plurality of jet holes 96b which are disposed in the main body section 96a toward the lower side on the cutting blade 93 side and which jet the chemical liquid L1 toward the wafer W held by the chuck table 8a, and a chemical liquid introduction port 96c formed at an end part on the depth side of the main body section 96a. A chemical liquid supply unit 13 for supplying the chemical liquid L1 is connected to the chemical liquid introduction port 96c. The chemical liquid supply nozzle 96 is fixed to the cover 94 or the rotary shaft housing 91 by an unillustrated fixing member or members, and is moved as one body with the cutting unit 9.

The chemical liquid supply unit 13 includes a chemical liquid storage tank 13a that stores the chemical liquid L1, a chemical liquid passage 13b that connects the chemical liquid storage tank 13a and the chemical liquid introduction port 96c, and an on-off valve 13c for closing and opening the chemical liquid passage 13b. The chemical liquid storage tank 13a includes an unillustrated pump, and, by operating the pump and opening the on-off valve 13c, the chemical liquid L1 can be jetted through the jet holes 96b of the chemical liquid supply nozzle 96.

The cutting liquid supply nozzle 95 depicted in broken line in FIG. 2 is disposed adjacent to the cutting unit 9. In the present embodiment, the cutting liquid supply nozzle 95 is formed inside the first cover member 94a, and supplies the cutting liquid L2 introduced via a cutting liquid introduction port 95a, toward the contact point of the cutting blade 93 and the wafer W to be cut. A cutting liquid supply unit 14 is connected to the cutting liquid introduction port 95a. The cutting liquid supply unit 14 includes a cutting liquid storage tank 14a that stores the cutting liquid L2, a cutting liquid passage 14b that connects the cutting liquid storage tank 14a and the cutting liquid introduction port 95a, and an on-off valve 14c for closing and opening the cutting liquid passage 14b. The cutting liquid storage tank 14a includes an unillustrated pump, and, by operating the pump and opening the on-off valve 14c, the cutting liquid L2 can be jetted from a jet port 95b of the cutting liquid supply nozzle 95.

The chemical liquid L1 in the present embodiment will be described below. The chemical liquid L1 adopted in the present invention is a chemical liquid which is used for a main purpose of preventing adhesion of cutting swarf generated by cutting to the front surface of the workpiece (in the present embodiment, the wafer W of silicon). Various chemical liquids having different effects as set forth below can be adopted according to the cutting conditions and the status of the workpiece. Note that the chemical liquid to be adopted in the present invention is not limited to Chemical Liquids 1 to 6 described below, and any chemical liquid that prevents adhesion of the cutting swarf generated by cutting to the front surface of the workpiece is not excluded from the present invention.

<Chemical Liquid 1>

Mixed water of ammonia and aqueous hydrogen peroxide: excellent in removal of particles.

<Chemical Liquid 2>

A citric acid solution: excellent in removal of heavy metal elements.

<Chemical Liquid 3>

Mixed water of sulfuric acid and aqueous hydrogen peroxide: excellent in removal of organic matter.

<Chemical Liquid 4>

Ozone water: excellent in removal of metals and organic matter.

<Chemical Liquid 5>

A mixed liquid of phosphoric acid and buffered hydrofluoric acid: excellent in removal of particles of insulating films.

<Chemical Liquid 6>

A phosphoric acid solution: excellent in removal of metallic impurities. When this solution is used, its temperature is raised to 35° C. to 50° C.

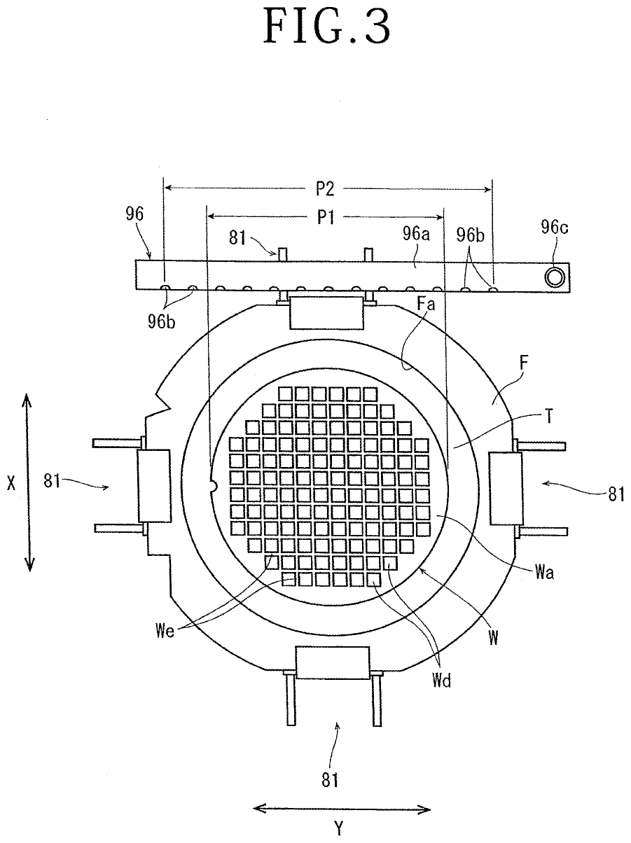

The above-described chemical liquid supply nozzle 96 is for supplying the chemical liquid L1 such that the cutting swarf scattered on the front surface Wa of the wafer W held by the chuck table 8a during cutting would not be adhered, and in the chemical liquid supply nozzle 96 and the wafer W held by the above-mentioned chuck table 8a are set to satisfy the following conditions described based on FIG. 3. Note that FIG. 3 is a plan view depicting the wafer W held by the chuck table 8a of the holding unit 8 and the chemical liquid supply nozzle 96 disposed in the cutting unit 9, in which, for convenience of explanation, those configurations of the cutting unit 9 which are other than the chemical liquid supply nozzle 96 (the cover 94, the rotary shaft housing 81, and the like) are omitted. The wafer W is a wafer formed on its front surface Wa with a plurality of devices Wd in the state of being partitioned by streets We, and the wafer W is held by an annular frame F having an opening Fa capable of accommodating the wafer W, with an adhesive tape T therebetween.

As understood from the plan view of FIG. 3, the chemical liquid supply nozzle 96 is disposed along the Y-axis direction, and has a length in the Y-axis direction which is greater than a width P1 in the Y-axis direction of the workpiece (in the present embodiment, the wafer W). In addition, in a case where the plurality of jet holes 96b formed in the main body section 96a of the chemical liquid supply nozzle 96 are not present over the whole region in the longitudinal direction of the main body section 96a, a length P2 defined by the jet hole 96b at an end part on one side and the jet hole 96b at an end part on the other side is set to be longer than the width P1 of the workpiece, as depicted in FIG. 3. Further, the number and the intervals of the plurality of jet holes 96b formed are set in such a manner that the chemical liquid L1 is supplied through the jet holes 96b to the whole region in the width direction of the workpiece held by the chuck table 8a. Note that, in the above-described embodiment, the chemical liquid supply nozzle 96 is formed with the plurality of jet holes 96b to supply the chemical liquid L1 therethrough, but the present invention is not limited to this configuration, and the chemical liquid L1 may be supplied through a slit formed along the longitudinal direction of the chemical liquid supply nozzle 96. In this case, the length of the slit is set in a size greater than the length of the width P1 of the above-mentioned workpiece. The chemical liquid supply unit 13, the cutting liquid supply unit 14, and each operating section described above are controlled by the above-mentioned controller.

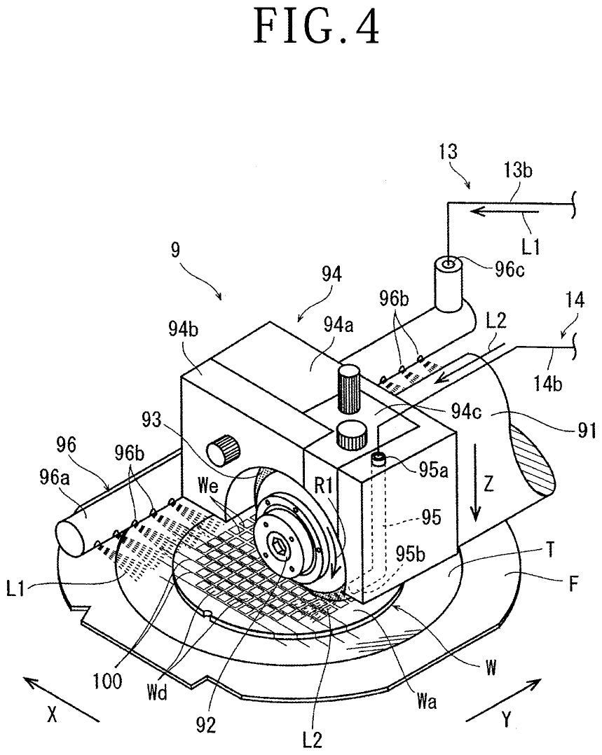

The cutting apparatus 1 of the present embodiment is configured substantially as described above, and a mode of cutting the wafer W as a workpiece by the cutting apparatus 1 will be described below. Note that the workpiece in the present invention is the plate-shaped wafer W as depicted in FIG. 4, which is formed with the plurality of devices Wd on the front surface Wa thereof partitioned by the streets We.

At the time of performing cutting by the cutting unit 9 of the cutting apparatus 1 described based on FIG. 1, first, the wafer W accommodated in the cassette 4 is conveyed out onto the temporary placement table 5 by the conveying-in/out unit 6, and is conveyed onto the chuck table 8a positioned at the conveying-in/out position in FIG. 1, by the conveying mechanism 7. After the wafer W is mounted on the chuck table 8a and held under suction, the wafer W is positioned at a position directly under the imaging unit 12 by the X-axis feeding mechanism omitted in illustration and is imaged, and a predetermined street We extending in a first direction of the wafer W in a region to be cut is detected and is matched to the X-axis direction. Next, alignment of the street We at which cutting is to be started and the cutting blade 93 of the cutting unit 9 is conducted, and the cutting unit 9 is positioned at a predetermined processing start position.

Subsequently, as depicted in FIG. 4, the cutting blade 93 of the cutting unit 9 is rotated at high speed in the direction indicated by an arrow R1 and is positioned on the street We having been matched to the X-axis direction, then the above-mentioned chemical liquid supply unit 13 and cutting liquid supply unit 14 are operated to jet the chemical liquid L1 and the cutting liquid L2 from the chemical liquid supply nozzle 96 and the cutting liquid supply nozzle 95, respectively. Then, the above-mentioned cutting-in feeding mechanism is operated to cause the cutting blade 93 to cut into the wafer W in the Z-axis direction from the front surface Wa side of the wafer W, and the above-mentioned X-axis feeding mechanism is operated to put the wafer W into processing-feeding in the X-axis direction indicated by an arrow X in FIG. 4, thereby forming a cut groove 100.

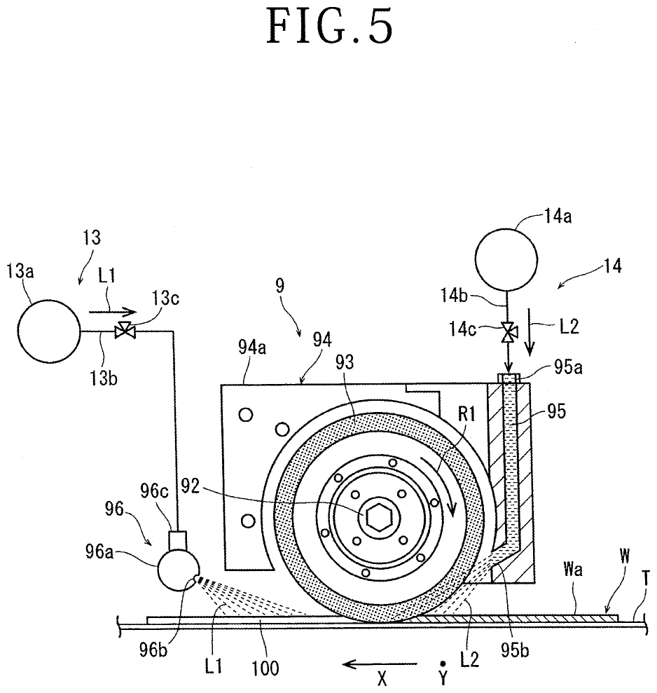

A front view of the cutting for forming the above-mentioned cut groove 100 according to the embodiment is depicted in FIG. 5. In FIG. 5, for convenience of explanation, the second cover member 94b and the cutting blade detection block 94c of the cover 94 are omitted, and a part of the first cover member 94a formed with the cutting liquid supply nozzle 95 is depicted in section.

As understood from FIGS. 4 and 5, the above-mentioned chemical liquid L1 is supplied onto the front surface Wa of the wafer W from the jet holes 96b of the chemical liquid supply nozzle 96 of the chemical liquid supply unit 13, so that the cutting swarf (contaminants) scattered from the contact point between the cutting blade 93 and the wafer W during formation of the cut groove 100 is prevented from being adhered to the front surface Wa of the wafer W. Incidentally, there is a fear that a bonding agent (for example, nickel plating) constituting the cutting edge of the cutting blade 93 is corroded due to the influence of this chemical liquid L1, thereby lowering the quality of cutting. In the present embodiment, however, the cutting liquid L2 is supplied from the cutting liquid supply nozzle 95 toward the contact point between the cutting blade 93 and the wafer W as the workpiece. As a result, corrosion of the cutting edge which might be generated under the influence of the chemical liquid L1 supplied onto the front surface Wa of the wafer W can be prevented. As the cutting liquid L2, for example, either pure water or a neutral surface active agent solution is preferably selected, and, as a result, corrosion of the cutting edge of the cutting blade 93 can be prevented, and lubricating properties and cooling properties for the cutting edge can be maintained. Note that, as the neutral surface active agent, there can be used, for example, a fatty acid salt, a synthetic detergent, and the like.

After the above-mentioned cut groove 100 is formed, the cutting blade 93 of the cutting unit 9 is put to indexing-feeding onto an unprocessed street We which extends in the first direction and which is adjacent in the Y-axis direction to the street We formed with the cut groove 100, and the cut groove 100 is formed similarly to the above. By repeating these operations, the cut grooves 100 are formed along all the streets We extending in the first direction. Next, the wafer W is rotated by 90 degrees, to match the streets We extending in a second direction orthogonal to the first direction to the X-axis direction, and, while the above-mentioned chemical liquid L1 and cutting liquid L2 are supplied, cutting is carried out on all the streets We extending in the second direction, whereby the cut grooves 100 are formed along all the streets We formed on the wafer W. By the above operations, the devices Wd of the wafer W are divided into individual device chips.

According to the cutting apparatus 1 of the embodiment described above, the cutting swarf can be efficiently washed away from the front surface Wa of the wafer W, the lubricating properties and cooling properties for the cutting edge of the cutting blade 93 can be maintained while corrosion of the cutting edge is prevented, and the wafer W can be divided along the streets We into the individual device chips.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting apparatus comprising:
a chuck table that holds a workpiece;
a cutting unit having, in a rotatable manner, a cutting blade for cutting the workpiece held by the chuck table;
an X-axis feeding mechanism for relative cutting-feeding of the chuck table and the cutting unit in an X-axis direction;
a Y-axis feeding mechanism for relative indexing-feeding of the chuck table and the cutting unit in a Y-axis direction orthogonal to the X-axis direction;
a cutting liquid supply nozzle that is disposed adjacent to the cutting unit and supplies a cutting liquid to a contact point between the cutting blade and the workpiece; and
a chemical liquid supply nozzle that has a length in the Y-axis direction which is greater than a width of the workpiece and supplies a chemical liquid for preventing adhesion of cutting swarf to a front surface of the workpiece.

2. The cutting apparatus according to claim 1,
wherein the cutting liquid supply nozzle supplies pure water or an aqueous solution of a neutral surface active agent, and
the chemical liquid supply nozzle supplies a chemical liquid selected from a group consisting of ammonia and aqueous hydrogen peroxide, a citric acid solution, sulfuric acid and aqueous hydrogen peroxide, ozone water, phosphoric acid and buffered hydrofluoric acid, and a phosphoric acid solution.
